(19) United States
(12) Patent Application Publication
(10) Pub. No.: US 2025/0218782 A1
(43) Pub. Date: Jul. 3, 2025

(54) METHOD OF MANUFACTURING SEMICONDUCTOR DEVICE

(71) Applicants: SAMSUNG ELECTRONICS CO, LTD., Suwon-si (KR); INCHEON NATIONAL UNIVERSITY RESEARCH & BUSINESS FOUNDATION, Incheon (KR)

(72) Inventors: Eunhyoung CHO, Suwon-si (KR); Jeongyub LEE, Suwon-si (KR); Youngchul LEEM, Suwon-si (KR); Hanboram LEE, Incheon (KR)

(73) Assignees: SAMSUNG ELECTRONICS CO, LTD., Suwon-si (KR); INCHEON NATIONAL UNIVERSITY RESEARCH & BUSINESS FOUNDATION, Incheon (KR)

(21) Appl. No.: 18/953,877

(22) Filed: Nov. 20, 2024

(30) Foreign Application Priority Data
Jan. 3, 2024 (KR) 10-2024-0001069
Mar. 11, 2024 (KR) 10-2024-0033863

(51) Int. Cl. H01L 21/285; C23C 16/04; C23C 16/06; C23C 16/455

(52) U.S. Cl. CPC H01L 21/28562; C23C 16/04; C23C 16/06; C23C 16/45536

(57) ABSTRACT

Provided is a method of manufacturing a semiconductor device including a dielectric layer including a first surface and a second surface that is more acidic than the first surface is formed on a semiconductor pattern, a reaction inhibitor is adsorbed onto one of the first surface and the second surface through an acid-base reaction, and a target layer is selectively formed through an atomic layer deposition process on a surface, on which the reaction inhibitor is not adsorbed, among the first surface and the second surface.

### CROSS-REFERENCE TO RELATED APPLICATION

This application is based on and claims priority under 35 U.S.C. § 119 to Korean Patent Application No. 10-2024-0001069 filed on Jan. 3, 2024, in the Korean Intellectual Property Office, and Korean Patent Application No. 10-2024-0033863, filed on Mar. 11, 2024, in the Korean Intellectual Property Office, the disclosures of which are incorporated by reference herein in their entireties.

### BACKGROUND

### 1. Field

The disclosure relates to a method of manufacturing a semiconductor device, and more particularly, to a method of manufacturing a semiconductor device by using a selective atomic layer deposition process.

### 2. Description of the Related Art

Semiconductor devices may include integrated circuits made up of metal oxide semiconductor field-effect transistors (MOSFETs). The size and design rules of semiconductor devices have gradually reduced, and thus, the scale-down of MOSFETs has also accelerated. A decrease in the size of MOSFETs may deteriorate the operating characteristics of semiconductor devices. Therefore, research has been conducted into methods of forming high-performance semiconductor devices that overcome limitations caused by the high degree of integration of semiconductor devices.

### SUMMARY

According to an aspect of the disclosure, there is provided a method of manufacturing a semiconductor device, the method including forming a dielectric layer on a semiconductor pattern, the dielectric layer including a first surface and a second surface, and the second surface is more acidic than the first surface; adsorbing, through an acid-base reaction, a reaction inhibitor onto a first one of the first surface and the second surface; and selectively forming, through an atomic layer deposition process, a target layer on a second one, on which the reaction inhibitor is not adsorbed, of the first surface and the second surface.

Adsorbing the reaction inhibitor onto the first one of the first surface and the second surface may include at least one of the reaction inhibitor being adsorbed onto the second surface when the reaction inhibitor is basic, and the reaction inhibitor being adsorbed onto the first surface when the reaction inhibitor is acidic.

The second surface may have a greater surface acidity than a surface acidity of the first surface.

A difference between a surface acidity of the second surface and a surface acidity of the first surface may be 1 pH or more.

The first surface may include at least one selected from oxides, nitrides, and oxynitrides, and the second surface may include an oxide.

The first surface may include at least one selected from HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, and SisN₄.

The second surface may include at least one selected from SiO₂, SnO₂, GeO₂, MnO₂, WO₃, and MOO₃.

A negative logarithm of an acid dissociation constant (pKa) of the reaction inhibitor may be within a range of 10 to 12.

The reaction inhibitor may include at least one selected from dimethylamino trimethylsilane (DMATMS), dimethylamino dimethylsilane (DMADMS), diethylamino trimethylsilane (DEATMS), and diethylamino dimethylsilane (DEADMS)

The target layer may include a conductive material.

The target layer may include at least one selected from copper (Cu), aluminum (Al), tungsten (W), cobalt (Co), silver (Ag), gold (Au), platinum (Pt), iridium (Ir), rhodium (Rh), and ruthenium (Ru).

Selectively forming, through the atomic layer deposition process, the target layer on the second one, on which the reaction inhibitor is not adsorbed, of the first surface and the second surface may include separating, by a reactant for forming the target layer, the reaction inhibitor from the surface on which the reaction inhibitor is adsorbed.

The reactant may include at least one selected from ozone plasma and oxygen plasma.

The dielectric layer may include a three-dimensional surface.

The first surface and the second surface may include a step difference from each other.

The second surface may be protruded outward relative to the first surface.

The semiconductor pattern may include a channel of a first transistor and a channel of a second transistor, a region of the dielectric layer corresponding to the first surface may include a gate insulating layer of the first transistor, a gate insulating layer of the second transistor may be included between the semiconductor pattern and a region of the dielectric layer corresponding to the second surface.

A gate electrode of the second transistor may be further included between the gate insulating layer of the second transistor and the region of the dielectric layer corresponding to the second surface.

The target layer may be a gate electrode of the first transistor and may include a material different from a material included in a gate electrode of the second transistor.

The semiconductor device may include a substrate, and the first transistor and the second transistor may be arranged in a direction perpendicular to a surface of the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A, FIG. 1B, FIG. 1C, and FIG. 1D are views illustrating some processes of manufacturing a semiconductor device, according to one or more embodiments;

FIG. 2 is a view illustrating the surface acidities of metal oxides, according to one or more embodiments;

FIG. 3 is a view illustrating results obtained by forming a target layer after treatment with a reaction inhibitor, according to one or more embodiments;

FIG. 4A, FIG. 4B, FIG. 4C, FIG. 4D, and FIG. 4E are views illustrating a method of forming a target layer on a dielectric layer having three different surface characteristics, according to one or more embodiments;

FIG. 5 is a transmission electron microscope (TEM) image illustrating results of a selective atomic layer deposition process performed using a reaction inhibitor having an aldehyde reactive group, according to one or more embodiments;

FIG. 6A is a view illustrating a process of removing a reaction inhibitor while forming a target layer, according to one or more embodiments;

FIG. 6B is a view illustrating a process of removing a reaction inhibitor while forming a target layer, according to one or more embodiments;

FIG. 6C is a view illustrating a process of simultaneously forming a plurality of target layers, according to one or more embodiments;

FIG. 7 is a plan view illustrating a three-dimensional semiconductor device according to one or more embodiments;

FIG. 8A, FIG. 8B, and FIG. 8C are cross-sectional views respectively taken along lines A-A′, B-B′, and C-C′ of FIG. 7; and

FIG. 9A, FIG. 9B, FIG. 9C, FIG. 9D, FIG. 9E, FIG. 9F, and FIG. 9G are views illustrating a method of forming a gate electrode of the three-dimensional semiconductor device shown in FIG. 8C.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, methods of manufacturing semiconductor devices will be described according to various embodiments with reference to the accompanying drawings. In the drawings, like reference numerals refer to like elements, and the sizes of elements may be exaggerated for clarity of illustration.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes or thicknesses of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. In the following descriptions of the embodiments, a material of each layer is merely an example, and another material may be used.

Furthermore, line connections or connection members between elements depicted in the drawings represent functional connections and/or physical or circuit connections by way of example, and in actual applications, they may be replaced or embodied as various additional functional connections, physical connections, or circuit connections.

An element referred to with the definite article or a demonstrative determiner may be construed as the element or the elements even though it has a singular form.

Expressions such as “at least one” preceding a list of elements specify the entire list of elements and do not specify individual elements within the list. For example, expressions such as “at least one of A, B, and C” or “at least one selected from the group consisting of A, B, and C” may be interpreted as indicating only A, only B, only C, or any combination of two or more of A, B, and C such as ABC, AB, BC, and AC.

When terms such as “approximately” or “substantially” are used in relation to a numerical value, the numerical value may be interpreted as including manufacturing or operational variations from the numerical value (for example, a variation of ±10%). Furthermore, when terms such as “generally” and “substantially” are used in relation to geometric shapes, geometric precision may not be required, and permissible variations of the geometric shapes may be within the scope of embodiments. In addition, regardless of whether numerical values or shapes are qualified or described by “approximately” or “substantially,” the numerical values or shapes may be interpreted as including manufacturing or operational variations from the numerical values or shapes (for example, a variation of ±10%).

It will be understood that although terms such as “first” and “second” are used herein to describe various elements, these elements should not be limited by these terms. These terms are only used to distinguish one element from other elements.

Examples or exemplary terms are just used herein to describe technical ideas and should not be considered for purposes of limitation unless defined by the claims.

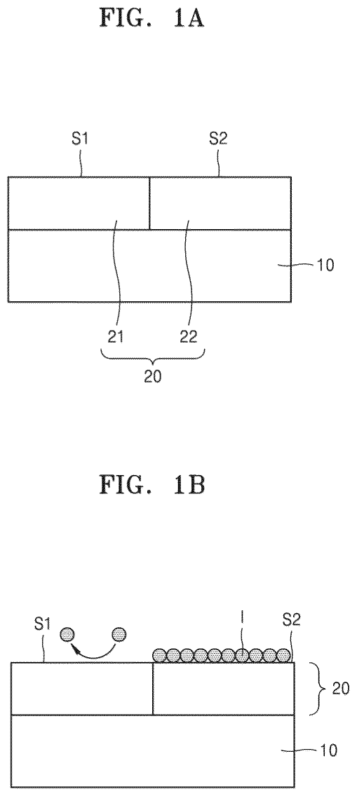

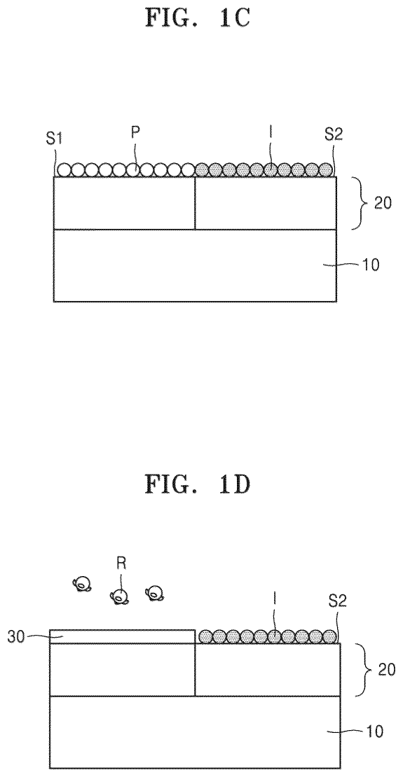

FIG. 1A, FIG. 1B, FIG. 1C, and FIG. 1D are views illustrating some processes of manufacturing a semiconductor device, according to an embodiment.

Referring to FIG. 1A, a dielectric layer 20 having a plurality of different surface characteristics may be formed on a semiconductor layer 10. The semiconductor layer 10 may include silicon, germanium, silicon germanium, or the like. Although FIG. 1A, FIG. 1B, FIG. 1C, and FIG. 1D illustrate the semiconductor layer 10 as one layer, the semiconductor layer 10 is not limited thereto. The semiconductor layer 10 may be a patterned semiconductor layer. Another material layer such as a conductive layer may be further disposed between the semiconductor layer 10 and the dielectric layer 20.

The dielectric layer 20 may include a plurality of materials having different characteristics. For example, the dielectric layer 20 may include a first region 21 including a first material and a second region 22 including a second material that is more acidic than the first material. In other words, the first material may have basic characteristics compared with the second material. Both the first region 21 and the second region 22 may be exposed to the outside. An exposed surface of the first area 21 may be referred to as a first surface S1, and an exposed surface of the second area 22 may be referred to as a second surface S2.

The first material and the second material may be chemically similar materials. For example, both the first material and the second material may be oxides. For example, the first material may include at least one selected from HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, and Si₃N₄. The second material may include at least one selected from SiO₂, SnO₂, GeO₂, MnO₂, WO₃, and MOO₃.

When both the first and second materials are oxides, their relative acidity or basicity may be determined by comparing the surface acidity of the first material with the surface acidity of the second material. The difference between the surface acidity of the first material and the surface acidity of the second material may be about 1 or more (in pH scale or the like). For example, the dielectric layer 20 may include a region containing hafnium oxide and a region containing silicon oxide. In this case, hafnium oxide may have basic characteristics compared with silicon oxide, and silicon oxide may have acidic characteristics compared with hafnium oxide. Alternatively, the dielectric layer 20 may include a region containing silicon oxide and a region containing manganese oxide. Silicon oxide may have basic characteristics compared with manganese oxide, and manganese oxide may have acidic characteristics compared with silicon oxide.

The first region 21 and the second region 22 may each include an oxide containing at least one selected from silver, magnesium, copper, zirconium, zinc, hafnium, chromium, aluminum, cobalt, iron, titanium, silicon, tin, germanium, manganese, tungsten, molybdenum, lithium, lead, scandium, tantalum, lanthanum, barium, strontium, and titanium.

Referring to FIG. 1B, a reaction inhibitor I may be adsorbed on a portion of a surface of the dielectric layer 20 through an acid-base reaction. The reaction inhibitor I may have basic characteristics. The negative logarithm of an acid dissociation constant (pKa) of the reaction inhibitor I may be about 11 to about 12. For example, the reaction inhibitor I that is a basic substance may include an aminosilane precursor P such as dimethylamino trimethylsilane (DMATMS), dimethylamino dimethylsilane (DMADMS), diethylamino trimethylsilane (DEATMS), or diethylamino dimethylsilane (DEADMS).

The reaction inhibitor I may be easily adsorbed on an acidic surface, for example, the second surface S2 of the dielectric layer 20, as a result of an acid-base reaction but may not be easily adsorbed on a basic surface, for example, the first surface S1 of the dielectric layer 20. In addition, the reaction inhibitor I may not react with at least one selected from a precursor P and a reactant R of a target layer 30 (described further herein below).

Although the reaction inhibitor I is described as having basic characteristics, the reaction inhibitor I is not limited thereto. The reaction inhibitor I may have acidic characteristics. In this case, the acidic reaction inhibitor I may be adsorbed on a basic surface among the first surface S1 and the second surface S2.

Referring to FIG. 1C, a precursor P may be provided on the dielectric layer 20. The precursor P may be formed on a surface of the dielectric layer 20 on which the reaction inhibitor I is not formed, for example, the first surface S1 of the dielectric layer 20. The precursor P does not react with the reaction inhibitor I and may thus be not easily formed on the second surface S2 of the dielectric layer 20 on which the reaction inhibitor I is adsorbed. The precursor P may be determined depending on a layer to be formed on the dielectric layer 20, that is, a material of the target layer 30 to be formed on the dielectric layer 20. When the target layer 30 is a conductive material layer, the precursor P may include copper (Cu), aluminum (Al), tungsten (W), cobalt (Co), silver (Ag), gold (Au), platinum (Pt), iridium (Ir), rhodium (Rh), or ruthenium (Ru).

Referring to FIG. 1D, the target layer 30 may be formed by providing a reactant R on the dielectric layer 20. The reactant R may react with the precursor P to form the target layer 30 but may not react with the reaction inhibitor I. The reactant R may include, for example, water, ammonia, hydrogen, oxygen, ozone, or the like.

After providing the precursor P as shown in FIG. 1C, a purge and discharge operation may be performed to remove a surplus of precursor P and by-products, and after forming the target layer 30 as shown in FIG. 1D, a purge and discharge operation may be performed to remove a surplus of the reactant R and by-products. Atomic layer deposition may have a basic cycle including an operation of providing a precursor P, an operation of purging and discharging a surplus of the precursor P, an operation of providing a reactant R, and an operation of purging and discharging a surplus of the reactant R. The basic cycle may be repeated until the target layer 30 is formed to a required thickness. For ease of description below, purge and discharge operations may not be explicitly described, and the processes described with reference to FIG. 1C and FIG. 1D may be collectively referred to as an atomic layer deposition process.

The atomic layer deposition process using the reaction inhibitor I may be performed to form the target layer 30 on a specific region of a surface, and thus, semiconductor device manufacturing processes may be simplified through the atomic layer deposition process. For example, when the target layer 30 has different surfaces having chemically similar characteristics, selective deposition efficiency may be improved by adsorbing the reaction inhibitor I through an acid-base reaction.

When the dielectric layer 20 has different surfaces formed of metal oxides, the surface acidity (SA) of the dielectric layer 20 based on Sanderson electronegativity may determine whether the surface of the dielectric layer 20 is acidic or basic.

The SA of a metal oxide may be defined by Equation 1 below.

$$SA = {N}_{m} - 2 {δ}_{m} \qquad - Equation 1$$

Here, Nₘ refers to the oxidation number of the metal oxide, δₘ refers to the Sanderson partial charge of metal ions, and the Sanderson partial charge δₘ of the metal ions may be defined by Equation 2 below.

$${δ}_{m} = \frac{( x + y ) \sqrt{( {( {S}_{{M}^{n +}} )}^{x} {( {S}_{E} )}^{y} )} - {S}_{{M}^{n +}}}{2.08 \sqrt{{S}_{{M}^{n +}}}} \qquad - Equation 2$$

Here, S_{M}ⁿ₊ and S_{E} respectively refer to the Sanderson electronegativity of the metal ions and the Sanderson electronegativity of the metal oxide in an oxidated state, x refers to the number of metals included in one molecule of the metal oxide, and y refers to the number of oxygens included in in one molecule of the metal oxide.

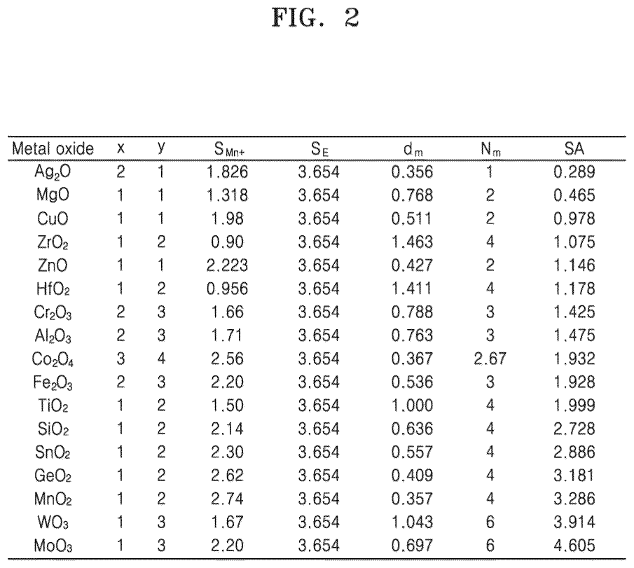

FIG. 2 is a view illustrating the surface acidities of metal oxides according to an embodiment.

FIG. 2 shows an example 200 such that different metal oxides have different surface acidities. A material having a great surface acidity may have acidic characteristics, and a material having a low surface acidity may have basic characteristics. When the surface of the dielectric layer 20 includes a first surface including a first metal oxide and a second surface including a second metal oxide, one of the first surface and the second surface may have relatively basic characteristics, and the other may have relatively acidic characteristics.

For example, when the dielectric layer 20 includes a first surface including hafnium oxide and a second surface including silicon oxide, the surface acidity of hafnium oxide is about 1.178, and the surface acidity of silicon oxide is about 2.728 as shown in FIG. 2. Therefore, the first surface including hafnium oxide may be a basic surface, and the second surface including silicon oxide may be an acidic surface. Whether surfaces are basic or acidic may be relatively determined. For example, silicon oxide may have acidic characteristics compared with hafnium oxide, but may also have basic characteristics compared with tungsten oxide.

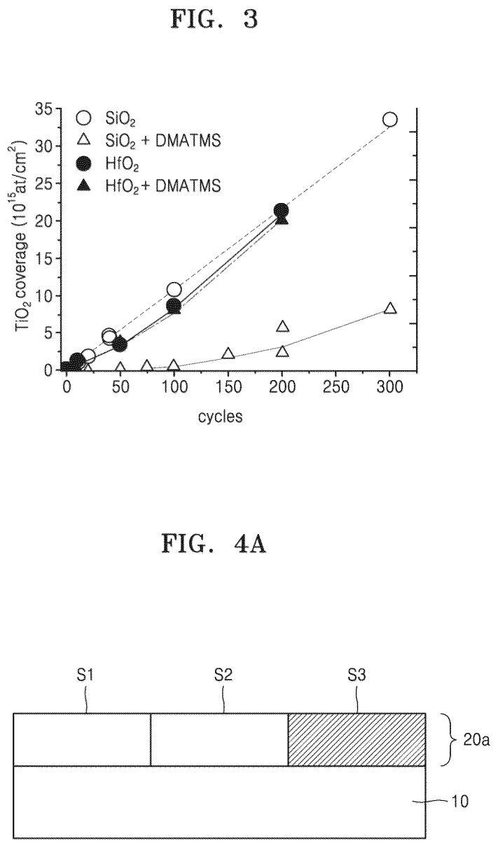

FIG. 3 is a view illustrating results obtained by forming a target layer after treatment with a reaction inhibitor I according to an embodiment. Referring to FIG. 3, weakly basic DMATMS is used as a reaction inhibitor I (refer to FIG. 1B, FIG. 1C, and FIG. 1D). It may be seen that the thickness of a titanium oxide layer formed as a target layer 30 (refer to FIG. 1D) on a silicon oxide layer and a hafnium layer that are not treated with DMATMS is proportional to the number of cycles of an atomic layer deposition process.

In addition, it may be seen that a titanium oxide layer is not formed on a silicon oxide layer treated with DMATMS until 100 cycles. Based on this, it may be inferred that DMATMS is adsorbed on silicon oxide and serves as a reaction inhibitor I inhibiting the formation of a titanium oxide layer.

It may be seen that as the number of cycles increases, the thickness of a titanium oxide layer formed on a hafnium oxide layer that is surface-treated with DMATMS increases, similar to the thickness of a titanium oxide layer formed on a hafnium oxide layer that is not surface-treated with DMATMS. This may indicate that DMATMS is not easily adsorbed on a hafnium oxide layer.

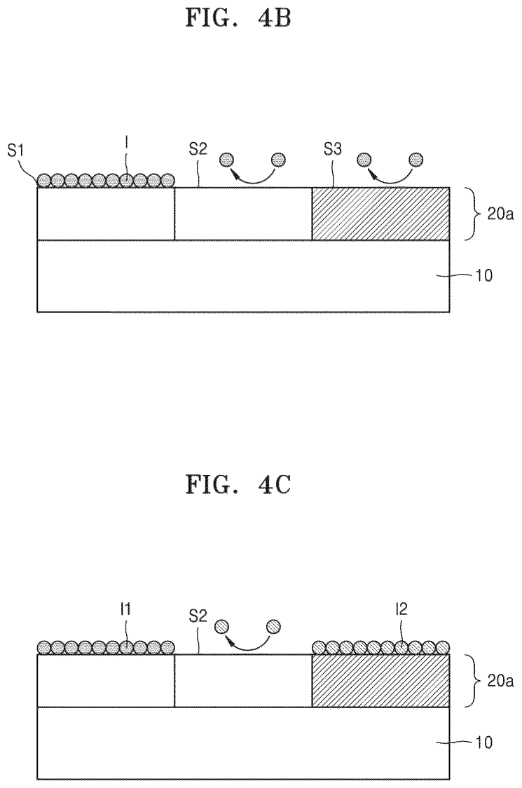

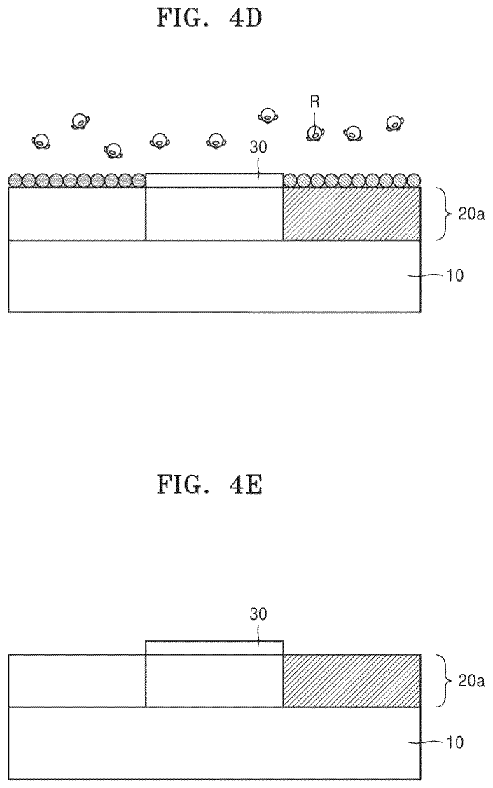

FIG. 4A. FIG. 4B, FIG. 4C, and FIG. 4E are views illustrating a method of forming a target layer on a dielectric layer having three different surface characteristics according to an embodiment.

Referring to FIG. 4A, a dielectric layer 20a having three different surface characteristics may be formed on a semiconductor layer 10. The semiconductor layer 10 may include silicon, germanium, silicon germanium, or the like. Although FIGS. 4A, FIG. 4B, FIG. 4C, and FIG. 4E illustrate the semiconductor layer 10 as one layer, the semiconductor layer 10 is not limited thereto. The semiconductor layer 10 may be patterned.

The dielectric layer 20a may include a first surface S1, a second surface S2, and a third surface S3 that have different characteristics. The first surface S1 and the second surface S2 may be chemically similar to each other, and the third surface S3 may not be chemically similar to the first surface S1 and the second surface S2. The first surface S1 and the second surface S2 may include a metal oxide and have different surface acidities, and the third surface S3 may include a material other than oxides. For example, the first surface S1 may include silicon oxide, the second surface S2 may include hafnium oxide, and the third substrate may include silicon nitride.

Referring to FIG. 4B, a first reaction inhibitor I1 may be adsorbed on one of the first surface S1 and the second surface S2 by an acid-base reaction. When the first reaction inhibitor I1 has basic characteristics, the first reaction inhibitor I1 may be adsorbed on a surface having acidic characteristics among the first surface S1 and the second surface S2. For example, when the first surface S1 includes a material having more acidic characteristics than the second surface S2, the first reaction inhibitor I1 may be adsorbed on the first surface S1. However, embodiments are not limited thereto. When the first reaction inhibitor I1 has acidic characteristics, the first reaction inhibitor I1 may be adsorbed on a surface having basic characteristics among the first surface S1 and the second surface S2.

Referring to FIG. 4C, a second reaction inhibitor I2 may be adsorbed on the third surface S3. The second reaction inhibitor I2 may include a material that may be adsorbed on a material included in the third surface S3 while not reacting with the first reaction inhibitor I1 and a material included in the first surface S1 and the second surface S2. For example, when the third surface S3 includes silicon nitride, the second reaction inhibitor I2 may include an aldehyde reactive group. For example, the second reaction inhibitor I2 may include at least one selected from formaldehyde, propionaldehyde, pivalaldehyde, benzaldehyde, and cyclohexanealdehyde (CHAD).

Referring to FIG. 4D, a target layer 30 may be formed on the second surface S2 by an atomic layer deposition method. At least one selected from a precursor and a reactant R that are for forming the target layer 30 may not react with the first reaction inhibitor I1 and the second reaction inhibitor I2. Therefore, the target layer 30 may not be formed on the first surface S1 and the third surface S3 but may be formed only on the second surface S2. That is, the target layer 30 may be selectively formed.

Referring to FIG. 4E, the first reaction inhibitor I1 and the second reaction inhibitor I2 may be removed from the first surface S1 and the third surface S3.

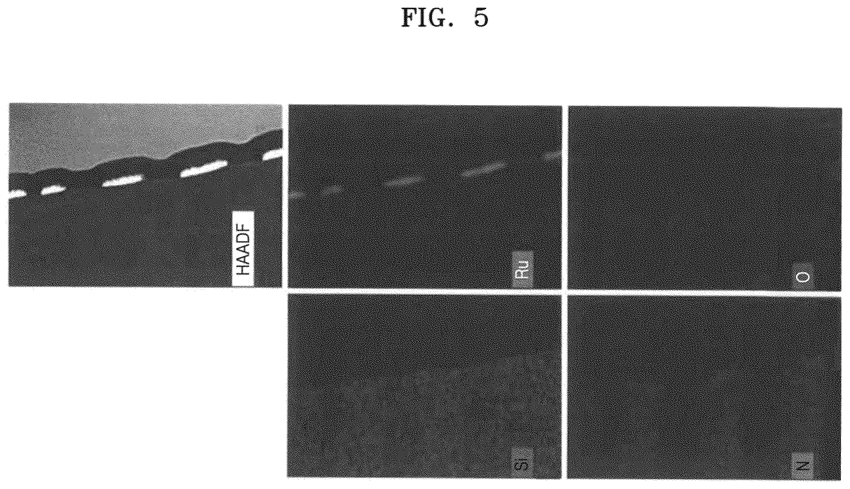

FIG. 5 is an example 500 of transmission electron microscope (TEM) images illustrating results of a selective atomic layer deposition process performed using a reaction inhibitor having an aldehyde reactive group according to an embodiment.

A reaction inhibitor having an aldehyde reactive group was provided on a dielectric layer on which a first surface including silicon oxide and a second surface including silicon nitride were alternately formed, and then, a ruthenium layer was grown on the dielectric layer through an atomic layer deposition process. FIG. 5 shows that the ruthenium layer was grown only on the surface including silicon oxide. The reason for this is that the ruthenium layer was not grown on the second surface including silicon nitride because the reaction inhibitor having an aldehyde reactive group was adsorbed on the second surface including silicon nitride.

In addition, deposition of a target layer and removal of the reaction inhibitor may be simultaneously performed depending on the type of the reaction inhibitor, the type of a precursor, and the type of a reactant.

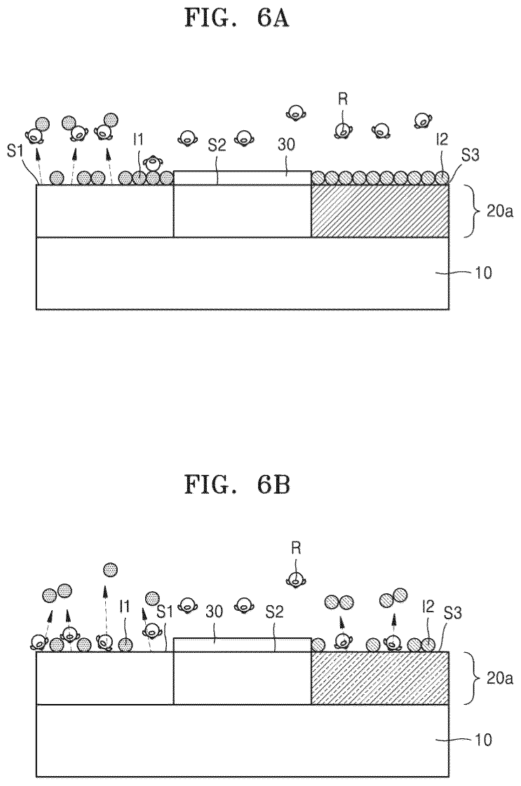

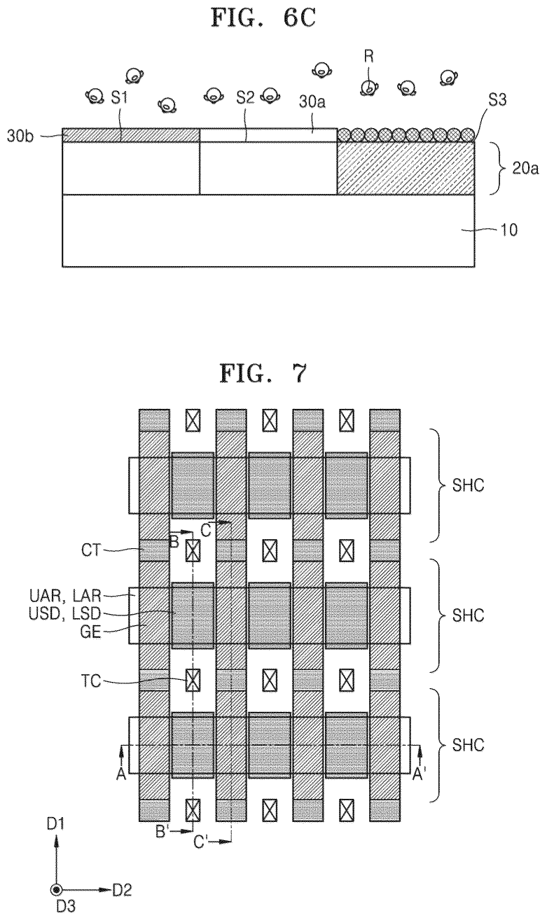

FIG. 6A is a view illustrating a process of removing a reaction inhibitor while forming a target layer 30, according to an embodiment. As shown in FIG. 6A, at least one selected from a first reaction inhibitor I1 and a second reaction inhibitor I2 may be removed at the same time when the target layer 30 is formed. For example, the first reaction inhibitor I1 may react with a reactant R of the target layer 30 and may thus generate a volatile product. For example, the first reaction inhibitor I1 may be tertiary butyl chloride (TBC) or tertiary butyl iodide (TBI). The first reaction inhibitor I1 may be removed by separating the volatile product from a first surface S1. That is, removal of the first reaction inhibitor I1 from the first surface S1 and formation of the target layer 30 on a second surface S2 may be simultaneously performed by providing the reactant R.

FIG. 6B is a view illustrating a process of removing a reaction inhibitor while forming a target layer 30, according to another embodiment. Referring to FIG. 6b, when a reactant R is a strong substance such as oxygen plasma or ozone plasma rather than water or ammonia, the reactant R may form the target layer 30 on a second surface S2, and at the same time, the reactor R may separate a first reaction inhibitor I1 and a second reaction inhibitor I2 respectively from a first surface S1 and a third surface S3.

FIG. 6C is a view illustrating a process of simultaneously forming a plurality of target layers according to an embodiment. Referring to FIG. 6C, when a reactant R is provided, the reactant R may form a first target layer 30a through a reaction with a precursor and a second target layer 30b through a reaction with a first reaction inhibitor I1. Different target layers, that is, the first and second target layers 30a and 30b, may be formed on a first surface S1 and a second surface S2 by using one reactant, that is, the reactant R.

The selective atomic layer deposition process using an acid-base reaction may be applied to a semiconductor device manufacturing process.

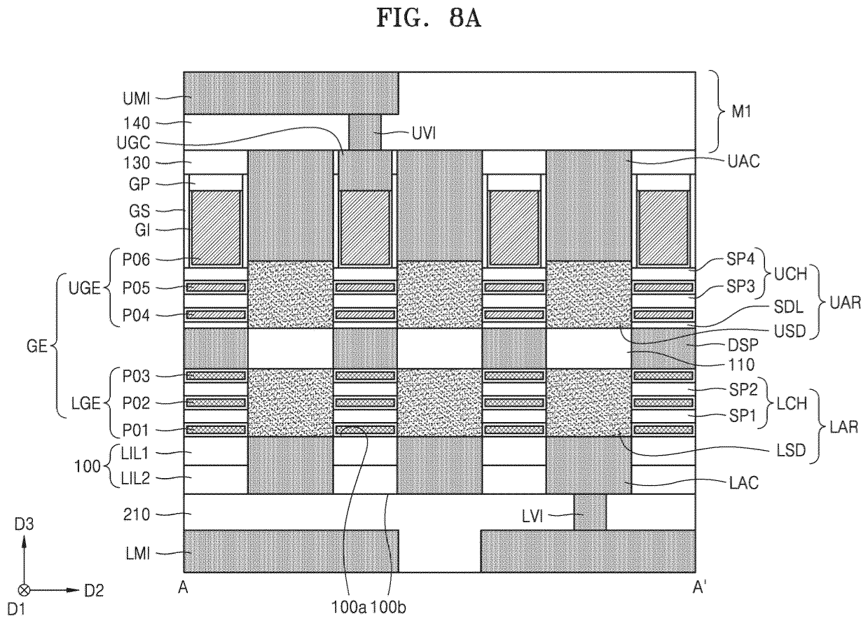

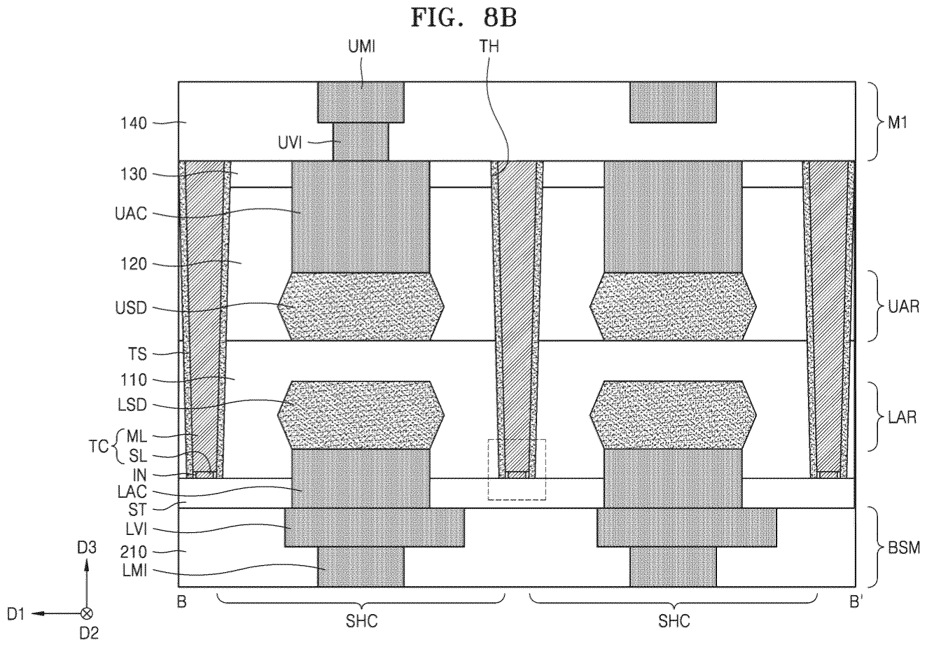

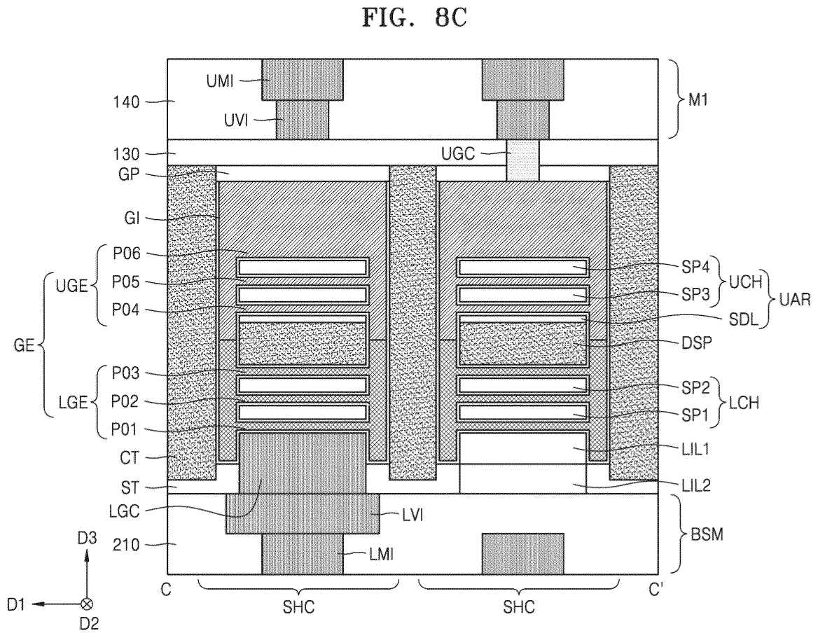

FIG. 7 is a plan view illustrating a three-dimensional semiconductor device according to an embodiment. FIG. 8A, FIG. 8B, and FIG. 8C are cross-sectional views respectively taken along lines A-A′, B-B′, and C-C′ of FIG. 7.

Referring to FIG. 7, FIG. 8A, FIG. 8B, and FIG. 8C, single-height cells SHC may be provided on a substrate 100. The substrate 100 may include a first surface 100a and a second surface 100b that face each other. A first side 100a may be a front side of the substrate 100, and a second side 100b may be a back side of the substrate 100. In an embodiment, the substrate 100 may be an insulating substrate including a silicon-based insulating material (for example, silicon oxide and/or silicon nitride). In another embodiment, the substrate 100 may be a semiconductor substrate including silicon, germanium, silicon germanium, or the like.

For example, the substrate 100 may include a first lower insulating layer LIL1 and a second lower insulating layer LIL2. The first lower insulating layer LIL1 may be provided on the second lower insulating layer LIL2. The first lower insulating layer LIL1 may include a silicon-based insulating material (for example, silicon oxide) and/or a semiconductor material (Si or SiGe). The second lower insulating layer LIL2 may include a silicon-based insulating material (for example, silicon oxide, silicon oxynitride, or silicon nitride).

Device isolation layers ST may be provided in the substrate 100. The device isolation layers ST may define the single-height cells SHC. In a plan view, the single-height cells SHC may be defined between device isolation layers ST that are adjacent to each other in a first direction D1. The device isolation layers ST may be arranged between a back metal layer BSM (described later) and through-conductive patterns TC (described layer). For example, the device isolation layers ST may include a silicon-based insulating material (for example, silicon oxide, silicon oxynitride, or silicon nitride).

In an embodiment, each of the single-height cells SHC may be a logic cell that forms a logic circuit. Each of the single-height cells SHC may be a logic cell including a three-dimensional device. The single-height cells SHC may be arranged in the first direction D1.

Each of the single-height cells SHC may include a lower active region LAR and an upper active region UAR that are sequentially stacked on the substrate 100. One of the lower and upper active regions LAR and UAR may be a P-type metal oxide semiconductor field-effect transistor (PMOSFET) region, and the other may be an N-type metal oxide semiconductor field-effect transistor (NMOSFET) region. The lower active region LAR may be provided in a bottom tier of a front-end-of-line (FEOL) layer, and the upper active region UAR may be provided in a top tier of the FEOL layer. An NMOSFET and a PMOSFET of the lower and upper active regions LAR and UAR may be vertically stacked to form three-dimensionally stacked transistors. In an embodiment, the lower active region LAR may be an NMOSFET region, and the upper active region UAR may be a PMOSFET region. Each of the lower and upper active regions LAR and UAR may have a bar shape or a line shape extending in a second direction D2.

The lower active region LAR may include lower channel patterns LCH and lower source drain patterns LSD. The lower channel patterns LCH may be arranged between a pair of lower source drain patterns LSD. The lower channel patterns LCH may connect the pair of lower source drain patterns LSD to each other.

The lower channel patterns LCH may include a first semiconductor pattern SP1 and a second semiconductor pattern SP2 that are stacked apart from each other. Each of the first and second semiconductor patterns SP1 and SP2 may include silicon (Si), germanium (Ge), or silicon germanium (SiGe). For example, each of the first and second semiconductor patterns SP1 and SP2 may include crystalline silicon. Each of the first and second semiconductor patterns SP1 and SP2 may be a nanosheet. For example, the lower channel patterns LCH may further include one or more semiconductor patterns that are stacked apart from the second semiconductor pattern SP2.

The lower source drain patterns LSD may be provided on the substrate 100. Each of the lower source drain patterns LSD may be an epitaxial pattern formed through a selective epitaxial growth (SEG) process. For example, upper surfaces of the lower source drain patterns LSD may be higher than an upper surface of the second semiconductor pattern SP2 of the lower channel patterns LCH.

The lower source drain patterns LSD may be doped with a dopant and may have a first conductivity type. The first conductivity type may be an N-type or P-type. In the current embodiment, the first conductivity type may be an N-type. The lower source drain patterns LSD may include silicon (Si) and/or silicon germanium (SiGe).

A first interlayer insulating layer 110 may be provided on the lower source drain patterns LSD. The first interlayer insulating layer 110 may cover the lower source drain patterns LSD.

Lower active contacts LAC may be provided under the lower source drain patterns LSD. The lower active contacts LAC may be electrically connected to the lower source drain patterns LSD. The lower active contacts LAC may be buried in the substrate 100. The lower active contacts LAC may extend vertically from the second side 100b to the first side 100a of the substrate 100. The lower active contacts LAC may include a metal selected from copper (Cu), aluminum (Al), ruthenium (Ru), cobalt (Co), tungsten (W), and molybdenum (Mo).

The upper active region UAR may be provided on the first interlayer insulating layer 110. The upper active region UAR may include upper channel patterns UCH and upper source drain patterns USD. The upper channel patterns UCH may vertically overlap the lower channel patterns LCH. The upper source drain patterns USD may vertically overlap the lower source drain patterns LSD. The upper channel patterns UCH may be arranged between a pair of upper source drain patterns USD. The upper channel patterns UCH may connect the pair of upper source drain patterns USD to each other.

The upper channel patterns UCH may include a third semiconductor pattern SP3 and a fourth semiconductor pattern SP4 that are stacked apart from each other. The third and fourth semiconductor patterns SP3 and SP4 of the upper channel patterns UCH may include the same semiconductor material as the first and second semiconductor patterns SP1 and SP2 of the lower channel pattern LCH. Each of the third and fourth semiconductor patterns SP3 and SP4 may be a nanosheet. For example, the upper channel patterns UCH may further include one or more semiconductor patterns that are stacked apart from the fourth semiconductor pattern SP4.

At least one dummy channel pattern DSP may be arranged between the lower channel patterns LCH and the upper channel patterns UCH disposed above the lower channel patterns LCH. A seed layer SDL may be arranged between the dummy channel pattern DSP and the upper channel patterns UCH.

The dummy channel pattern DSP may be apart from the lower and upper source drain patterns LSD and USD. That is, the dummy channel pattern DSP may not be connected to any of the lower and upper source drain patterns LSD and USD. The dummy channel pattern DSP may include a semiconductor material such as silicon (Si), germanium (Ge), or silicon germanium (SiGe), or may include a silicon-based insulating material such as a silicon oxide layer or a silicon nitride layer. In an embodiment, the dummy channel pattern DSP may include a silicon-based insulating material.

The upper source drain patterns USD may be provided on an upper surface of the first interlayer insulating layer 110. Each of the upper source drain patterns USD may be an epitaxial pattern formed through an SEG process. For example, upper surfaces of the upper source drain patterns USD may be higher than an upper surface of the fourth semiconductor pattern SP4 of the upper channel patterns UCH.

The upper source drain patterns USD may be doped with a dopant and have a second conductivity type. The second conductivity type may be different from the first conductivity type of the lower source drain patterns LSD. The second conductivity type may be a P-type. The upper source drain patterns USD may include silicon germanium (SiGe) and/or silicon (Si).

A plurality of gate electrodes GE may be provided on the single-height cells SHC. For example, the gate electrodes GE may be provided on the lower and upper channel patterns LCH and UCH that are stacked. In a plan view, the gate electrodes GE may have a bar shape extending in the first direction D1. The gate electrodes GE may vertically overlap the lower and upper channel patterns LCH and UCH that are stacked.

The gate electrodes GE may extend in a vertical direction (that is, a third direction D3) from the first surface 100a of the substrate 100 to gate capping patterns GP. The gate electrodes GE may extend in the third direction D3 from the lower channel patterns LCH of the lower active region LAR to the upper channel patterns UCH of the upper active region UAR. The gate electrodes GE may extend in the third direction D3 from the first semiconductor patterns SP1 that are lowermost to the fourth semiconductor patterns SP4 that are uppermost.

The gate electrodes GE may be provided on a top surface, a bottom surface, and both side walls of each of the first pattern SP1, second semiconductor pattern SP2, third semiconductor pattern SP3, and fourth semiconductor pattern SP4. That is, transistors of the current embodiments may include three-dimensional field effect transistors (for example, multi-bridge channel field-effect transistors (MBCFETs) or gate-all-around field-effect transistors (GAAFETs)) in which channels are three-dimensionally surrounded by gate electrodes GE.

Each of the gate electrodes GE may include: a lower gate electrode LGE provided in the bottom tier of the FEOL layer, that is, in the lower active region LAR; and an upper gate electrode UGE provided in the top tier of the FEOL layer, that is, in the upper active region UAR. The lower gate electrode LGE and the upper gate electrode UGE may vertically overlap each other. In an embodiment, the lower gate electrode LGE and the upper gate electrode UGE are illustrated as being connected to each other. However, embodiments are not limited thereto. The lower gate electrode LGE and the upper gate electrode UGE may be apart from each other by an insulating material. The lower gate electrode LGE and the upper gate electrode UGE may include different conductive materials and may have different threshold voltages.

The lower gate electrode LGE may include a first inner electrode PO1 provided between a first active pattern and the first semiconductor pattern SP1, a second inner electrode PO2 provided between the first semiconductor pattern SP1 and the second semiconductor pattern SP2, and a third inner electrode PO3 provided between the second semiconductor pattern SP2 and the dummy channel pattern DSP.

The upper gate electrode UGE may include a fourth inner electrode PO4 provided between the dummy channel pattern DSP (or the seed layer SDL) and the third semiconductor pattern SP3, a fifth inner electrode PO5 provided between the third semiconductor pattern SP3 and the fourth semiconductor pattern SP4, and an outer electrode PO6 provided on the fourth semiconductor pattern SP4.

A pair of gate spacers GS may be disposed on both side walls of the gate electrode GE. The pair of gate spacers GS may be disposed on both side walls of the outer electrode PO6. The gate spacers GS may extend in the first direction D1 along the gate electrode GE. Upper surfaces of the gate spacers GS may be higher than an upper surface of the gate electrode GE. The upper surfaces of the gate spacers GS may be coplanar with an upper surface of a second interlayer insulating layer 120. The gate spacers GS may include at least one selected from SiCN, SiCON, and SiN. In another example, the gate spacers GS may each include multiple layers including at least two selected from SiCN, SiCON, and SiN.

The gate capping patterns GP may be provided on the upper surfaces of the gate electrodes GE. The gate capping patterns GP may extend in the first direction D1 along the gate electrodes GE. For example, the gate capping patterns GP may include at least one selected from SiON, SiCN, SiCON, and SiN.

A gate insulating layer GI may be arranged between the gate electrodes GE and the first to fourth semiconductor patterns SP1 to SP4. The gate insulating layer GI may include a silicon oxide layer, a silicon oxynitride layer, and/or a high-k dielectric layer. In an embodiment, the gate insulating layer GI may include: a silicon oxide layer that directly covers surfaces of the first to fourth semiconductor patterns SP1 to SP4; and a high-k dielectric layer provided on the silicon oxide layer. In other words, the gate insulating layer GI may have a multi-layer structure including the silicon oxide layer and the high-k dielectric layer.

The high-k dielectric layer may include a high-k dielectric material having a higher dielectric constant than the silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The second interlayer insulating layer 120 may be provided on the upper source drain patterns USD and the gate electrodes GE. The second interlayer insulating layer 120 may cover the upper source drain patterns USD. A third interlayer insulating layer 130 may cover the second interlayer insulating layer 120.

Upper active contacts UAC may be respectively electrically connected to the upper source and drain patterns USD through the second and third interlayer insulating layers 120 and 130. Upper surfaces of the upper active contacts UAC may be coplanar with an upper surface of the third interlayer insulating layer 130.

Upper gate contacts UGC may be electrically connected to the upper gate electrodes UGE through the third interlayer insulating layer 130 and the gate capping pattern GP. The upper active contacts UAC and the upper gate contacts UGC may each include a metal selected from copper (Cu), aluminum (Al), ruthenium (Ru), cobalt (Co), tungsten (W), and molybdenum (Mo).

Cutting patterns CT may be provided between the gate electrodes GE that are adjacent to each other in the first direction D1. The cutting patterns CT may separate the gate electrodes GE from each other. The gate electrodes GE may be separated apart from each other in the first direction D1 by the cutting patterns CT. The cutting patterns CT may each have a bar shape or a line shape extending in the second direction D2. The cutting patterns CT may include an insulating material such as silicon oxide and silicon nitride.

A fourth interlayer insulating layer 140 may be provided on the third interlayer insulating layer 130. A first metal layer M1 may be provided in the fourth interlayer insulating layer 140. The first metal layer M1 may include upper interconnections UMI. The first metal layer M1 may further include upper vias UVI. The upper vias UVI may electrically connect the upper interconnections UMI to the upper active contacts UAC or the upper gate contacts UGC. The upper interconnections UMI and the upper vias UVI may each include a metal selected from copper (Cu), aluminum (Al), ruthenium (Ru), cobalt (Co), tungsten (W), and molybdenum (Mo).

Additional metal layers (for example, M2, M3, M4, etc.) may be stacked on the first metal layer M1. The first metal layer M1 and the additional metal layers (for example, M2, M3, M4, etc.) stacked on the first metal layer M1 may form a back-end-of-line (BEOL) layer of the three-dimensional semiconductor device. The additional metal layers (for example, M2, M3, M4, etc.) stacked on the first metal layer M1 may include routing interconnections to connect logic cells to each other.

A lower interlayer insulating layer 210 may be provided under the second surface 100b of the substrate 100. The back metal layer BSM may be provided in the lower interlayer insulating layer 210. The back metal layer BSM may include lower interconnections LMI. The back metal layer BSM may further include lower vias LVI. The lower vias LVI may electrically connect the lower interconnections LMI to the lower active contacts LAC, lower gate contacts LGC, or lower contact patterns.

The lower interconnections LMI and the lower vias LVI may each include a metal selected from copper (Cu), aluminum (Al), ruthenium (Ru), cobalt (Co), tungsten (W), and molybdenum (Mo).

Additional lower metal layers may be stacked under the back metal layer BSM. In an embodiment, the lower metal layers may include a power transmission network. The power transmission network may include an interconnection network for applying a source voltage VSS and a drain voltage VDD to the back metal layer BSM.

The source voltage VSS and the drain voltage VDD may be applied to the back metal layer BSM through the power transmission network. Referring back to FIG. 8A, one of the source voltage VSS or the drain voltage VDD may be applied to the lower source drain patterns LSD through the lower interconnections LMI, the lower vias LVI, and the lower active contacts LAC. The other voltage may be applied from the back metal layer BSM to the first metal layer M1 through power tap cells. The other voltage applied to the first metal layer M1 through the power tap cells may be applied to the upper source drain patterns USD through the upper interconnections UMI, the upper vias UVI, and the upper active contacts UAC. The power tap cells may be arranged between adjacent single-height cells SHC.

The through-conductive patterns TC may penetrate the first interlayer insulating layer 110, second interlayer insulating layer 120, and third interlayer insulating layer 130 in the vertical direction (that is, the third direction D3). The through-conductive patterns TC may be provided in through-holes TH that penetrate the first interlayer insulating layer 110, second interlayer insulating layer 120 in the vertical direction. The through-conductive patterns TC may be arranged without restrictions from a planar perspective. For example, although FIG. 7 illustrates that the through-conductive patterns TC are two-dimensionally arranged in the first and second directions D1 and D2, embodiments are not limited thereto.

The through-conductive patterns TC may penetrate the first interlayer insulating layer 110, second interlayer insulating layer 120 to electrically connect the first metal layer M1 and the back metal layer BSM. The through-conductive patterns TC may be electrically connected to the first metal layer M1 through the upper vias UVI and to the back metal layer BSM through the lower contact patterns.

Each of the through-conductive patterns TC may include a seed layer SL and a main layer ML provided on the seed layer SL. A seam may not be provided in the main layer ML. An inhibitor IN may be provided on lateral surfaces of the seed layers SL of the through-conductive patterns TC. Through-spacers TS may be provided on lateral surfaces of the through-conductive patterns TC.

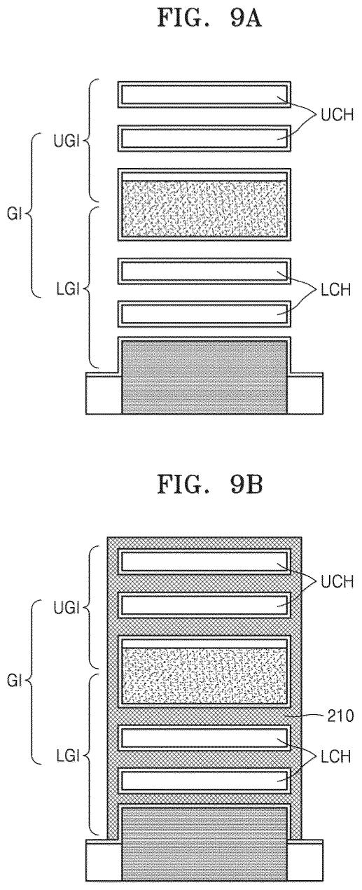

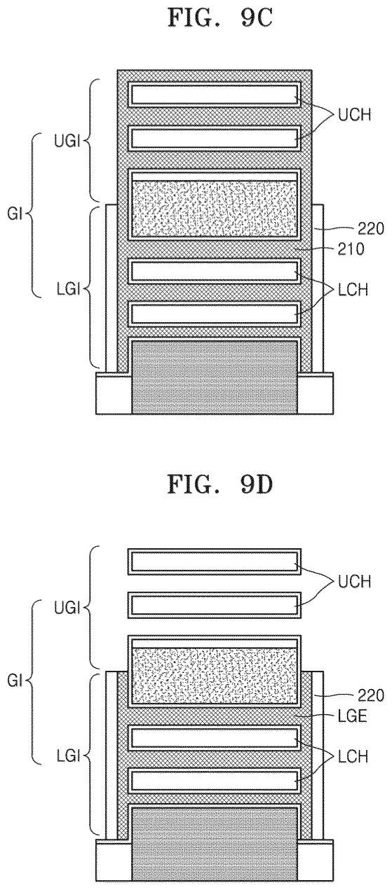

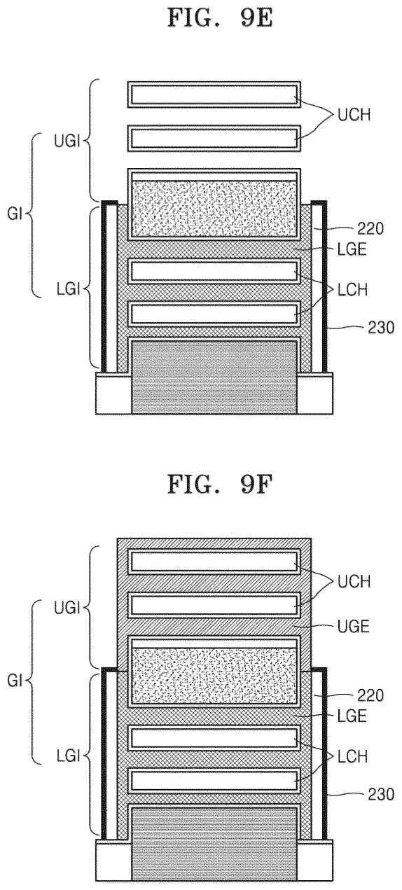

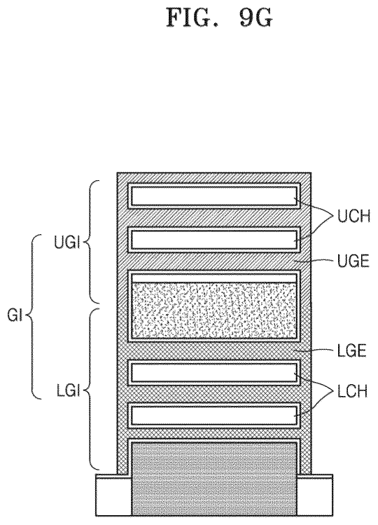

FIG. 9A, FIG. 9B, FIG. 9C, FIG. 9D, FIG. 9E, FIG. 9F, and FIG. 9G are views illustrating a method of forming a gate electrode of the three-dimensional semiconductor device shown in FIG. 8C.

Referring to FIG. 9A, a lower channel pattern LCH, a dummy channel pattern DSP, a seed layer SDL, and an upper channel pattern UCH may be sequentially formed on a substrate 100. In addition, a gate insulating layer GI may be formed to cover surfaces of the lower channel pattern LCH, the dummy channel pattern DSP, the seed layer SDL, and the upper channel pattern UCH. The gate insulating layer GI may include: an upper gate insulating layer UGI that covers the upper channel pattern UCH, the seed layer SDL, and a portion of the dummy channel pattern DSP; and a lower gate insulating layer LGI that covers the lower channel pattern LCH and the rest of the dummy channel pattern DSP.

The gate insulating layer GI may include a silicon oxide layer, a silicon oxynitride layer, and/or a high-k dielectric layer. In an embodiment, the gate insulating layer GI may include a silicon oxide layer directly covering surfaces of semiconductor patterns and a high-k dielectric layer provided on the silicon oxide layer. In other words, the gate insulating layer GI may have a multi-layer structure including the silicon oxide layer and the high-k dielectric layer. The high-k dielectric layer may include at least one selected from HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, and Si₃N₄.

Referring to FIG. 9B, a first conductive layer 210 may be formed to cover the gate insulating layer GI. The first conductive layer 210 may include at least one selected from W, TiN, TaN, WN, Re, Ir, Ru, Mo, Al, Cu, Co, Ni, and TiAlC. The first conductive layer 210 may be formed between the lower channel patterns LCH, between the upper channel patterns UCH, and on the lower channel patterns LCH, the seed layer SDL, and the upper channel patterns UCH.

Referring to FIG. 9C, a sacrificial pattern 220 may be formed on a region of the first conductive layer 210. The sacrificial pattern 220 may correspond to the lower gate insulating layer LGI. That is, the sacrificial pattern 220 may be formed on the first conductive layer 210 in a region covering the lower channel patterns LCH and a portion of the dummy channel pattern DSP. A region of the first conductive layer 210 that covers the upper channel patterns UCH and the seed layer SDL may be exposed to the outside. The sacrificial pattern 220 may include a spin-on-hard (SOH) mask material (for example, silicon oxide).

Referring to FIG. 9D, the region of the first conductive layer 210 that is exposed above the sacrificial pattern 220 may be removed. The upper gate insulating layer UGI may be exposed to the outside by removing the exposed region of the first conductive layer 210. The other region of the first conductive layer 210 that is not removed may be a lower gate electrode LGE.

Referring to FIG. 9E, a reaction inhibition layer 230 may be formed on the sacrificial pattern 220. The reaction inhibition layer 230 may be formed only on the sacrificial pattern 220 through an acid-base reaction.

The lower channel patterns LCH, the dummy channel pattern DSP, the seed layer SDL, and the upper channel patterns UCH may correspond to the semiconductor layer 10 described with reference to FIG. 1A, and the upper gate insulating layer UGI and the sacrificial pattern 220 may correspond to the dielectric layer 20 described with reference to FIG. 1A. That is, a dielectric layer of a semiconductor device may have a three-dimensional surface. A surface of the upper gate insulating layer UGI may correspond to the first surface S1 of the dielectric layer 20 described with reference to FIG. 1A, and a surface of the sacrificial pattern 220 may correspond to the second surface S2 of the dielectric layer 20 described with reference to FIG. 1A. That is, a first surface and a second surface of a dielectric layer may have a step difference from each other. The second surface may protrude outward relative to the first surface. The formation of the reaction inhibitor layer 230 may correspond to the adsorption of the reaction inhibitor described with reference to FIG. 1B. That is, during the acid-base reaction, the reaction inhibition layer 230 may be formed only on the sacrificial pattern 220 without being adsorbed on the upper gate insulating layer UGI.

Referring to FIG. 9F, a second conductive layer, that is, an upper gate electrode UGE, may be formed on the exposed upper gate insulating layer UGI. The upper gate electrode UGE may include a material that is different from a material included in the lower gate electrode LGE. The upper gate electrode UGE and the lower gate electrode LGE include different materials as described above, and thus, a lower transistor and an upper transistor may have different threshold voltages.

Referring to FIG. 9G, the sacrificial pattern 220 and the reaction inhibition layer 230 formed on the lower gate electrode LGE may be removed.

Because the upper gate insulating layer UGI and the sacrificial pattern 220 include similar metal oxide materials, a conductive material may be deposited on both the upper gate insulating layer UGI (hafnium oxide) and the sacrificial pattern 220. Thus, it may be difficult to remove only the sacrificial pattern 220 in a later process. In addition, other oxides may be present during semiconductor device manufacturing processes, and when a conductive material is deposited on the other oxides, various defects may occur.

According to an embodiment, the reaction inhibition layer 230 is formed only on a surface of the sacrificial pattern 220 through an acid-base reaction, and thus, a conductive material may be deposited only on the upper gate insulating layer UGI. Therefore, the yield of semiconductor device manufacturing processes may increase, and the occurrence of defects in a semiconductor device may reduce.

Although FIG. 9C, FIG. 9D, and FIG. 9E illustrate that the sacrificial pattern 220 and the reaction inhibition layer 230 are formed on a region of the first conductive layer 210, embodiments are not limited thereto. The sacrificial pattern 220 and the reaction inhibition layer 230 may also be formed on other regions including oxides in addition to the upper gate insulating layer UGI. A selective atomic layer deposition method using an acid-base reaction may be used to manufacture a variety of semiconductor devices in addition to the semiconductor devices described above.

As described above, according to the one or more of the above embodiments, the yield of semiconductor device manufacturing processes may be improved by forming a target layer only on a specific surface among a plurality of chemically similar surfaces through an acid-base reaction.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a semiconductor device, the method comprising:
forming a dielectric layer on a semiconductor pattern, the dielectric layer comprising a first surface and a second surface, and the second surface is more acidic than the first surface;
adsorbing, through an acid-base reaction, a reaction inhibitor onto a first one of the first surface and the second surface; and
selectively forming, through an atomic layer deposition process, a target layer on a second one, on which the reaction inhibitor is not adsorbed, of the first surface and the second surface.

2. The method of claim 1, wherein adsorbing the reaction inhibitor onto the first one of the first surface and the second surface comprises at least one of the reaction inhibitor being adsorbed onto the second surface when the reaction inhibitor is basic, and the reaction inhibitor being adsorbed onto the first surface when the reaction inhibitor is acidic.

3. The method of claim 1, wherein the second surface has a greater surface acidity than a surface acidity of the first surface.

4. The method of claim 1, wherein a difference between a surface acidity of the second surface and a surface acidity of the first surface is 1 pH or more.

5. The method of claim 1, wherein the first surface comprises at least one selected from oxides, nitrides, and oxynitrides, and
the second surface comprises an oxide.

6. The method of claim 1, wherein the first surface comprises at least one selected from HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, and Si₃N₄.

7. The method of claim 1, wherein the second surface comprises at least one selected from SiO₂, SnO₂, GeO₂, MnO₂, WO₃, and MOO₃.

8. The method of claim 1, wherein a negative logarithm of an acid dissociation constant (pKa) of the reaction inhibitor is within a range of 10 to 12.

9. The method of claim 1, wherein the reaction inhibitor comprises at least one selected from dimethylamino trimethylsilane (DMATMS), dimethylamino dimethylsilane (DMADMS), diethylamino trimethylsilane (DEATMS), and diethylamino dimethylsilane (DEADMS).

10. The method of claim 1, wherein the target layer comprises a conductive material.

11. The method of claim 1, wherein the target layer comprises at least one selected from copper (Cu), aluminum (Al), tungsten (W), cobalt (Co), silver (Ag), gold (Au), platinum (Pt), iridium (Ir), rhodium (Rh), and ruthenium (Ru).

12. The method of claim 1, wherein selectively forming, through the atomic layer deposition process, the target layer on the second one, on which the reaction inhibitor is not adsorbed, of the first surface and the second surface comprises separating, by a reactant for forming the target layer, the reaction inhibitor from the surface on which the reaction inhibitor is adsorbed.

13. The method of claim 12, wherein the reactant comprises at least one selected from ozone plasma and oxygen plasma.

14. The method of claim 1, wherein the dielectric layer comprises a three-dimensional surface.

15. The method of claim 1, wherein the first surface and the second surface have a step difference from each other.

16. The method of claim 1, wherein the second surface is protruded outward relative to the first surface.

17. The method of claim 1, wherein the semiconductor pattern comprises a channel of a first transistor and a channel of a second transistor,
a region of the dielectric layer corresponding to the first surface comprises a gate insulating layer of the first transistor,
a gate insulating layer of the second transistor is included between the semiconductor pattern and a region of the dielectric layer corresponding to the second surface.

18. The method of claim 17, wherein a gate electrode of the second transistor is further included between the gate insulating layer of the second transistor and the region of the dielectric layer corresponding to the second surface.

19. The method of claim 17, wherein the target layer is a gate electrode of the first transistor and comprises a material different from a material included in a gate electrode of the second transistor.

20. The method of claim 17, wherein the semiconductor device comprises a substrate, and
the first transistor and the second transistor are arranged in a direction perpendicular to a surface of the substrate.
